(19) United States
(12) Patent Application Publication
(10) Pub. No.: US 2014/0224526 A1
(43) Pub. Date: Aug. 14, 2014

(54) MULTI-LAYER FLEXIBLE CIRCUIT BOARD AND PROCESS FOR PRODUCING THE SAME

(71) Applicant: ICHIA TECHNOLOGIES, INC., Taoyuan County (TW)

(72) Inventors: CHIEN-HWA CHIU, TAOYUAN COUNTY (TW); CHIH-MIN CHAO, TAOYUAN COUNTY (TW); PEIR-RONG KUO, TAOYUAN COUNTY (TW); CHIA-HUA CHIANG, TAOYUAN COUNTY (TW); CHIH-CHENG HSIAO, TAOYUAN COUNTY (TW); FENG-PING KUAN, TAOYUAN COUNTY (TW); YING-WEI LEE, TAOYUAN COUNTY (TW); YUNG-CHANG JUANG, TAOYUAN COUNTY (TW)

(73) Assignee: ICHIA TECHNOLOGIES, INC., Taoyuan County (TW)

(21) Appl. No.: 13/852,014

(22) Filed: Mar. 28, 2013

(30) Foreign Application Priority Data
Feb. 8, 2013 (TW) 102105354

(51) Int. Cl. H05K 1/02; H05K 3/46; H05K 3/00

(52) U.S. Cl. CPC H05K 1/0216; H05K 3/0011; H05K 3/4644
USPC 174/251; 427/96.2; 216/13

(57) ABSTRACT

The present invention provides a multi-layer flexible circuit board, comprising at least an electric circuit disposed on a vertical interval layer, wherein at least two sides of the electric circuit are covered by neighboring interval layer and another vertical interval composed layer of electric insulating material. The disclosure provides a non-pressing way to stack the multi-layer flexible circuit board, preventing fault crevice derived from a prior-known pressing way.

### BACKGROUND OF THE INVENTION

1. Field of the Invention

The present invention relates to a multi-layer flexible circuit board and a process for producing the same; in particular, to a multi-layer flexible circuit board which uses an electric insulation layer to enclose at least two sides of the electric circuit and a process for producing the same.

2. Description of Related Art

Conventional flexible circuit boards are made by processing precursor substrates. The precursor substrates must be coated with a metal conducting layer to enable subsequent processing. Metals generally do not easily adhere to conventional precursor substrates. Conventional methods of coating metal include metal spraying, sputtering deposition, CVD, vapor deposition, and dry coating. However these methods result in problems of thick precursor substrates, or difficult and overly long coating processes. The excess thickness compromises the miniaturization of products.

Moreover, large thickness does not facilitate production of multi-layer flexible circuit boards. Difficult and overly long coating processes result in limited production capacity and raised production cost. Additionally, the pressing method used to produce most flexible circuit boards usually result in pressing defects, creating air bubbles due to disjunctions and poor yield rates.

Also, a multi-layer flexible circuit board has more electric circuits, leading to a more serious problem of crosstalk between electric circuits. This is also a problem waiting to be solved.

Hence, the present inventor believes the above mentioned disadvantages can be overcome, and through devoted research combined with application of theory, finally proposes the present disclosure which has a reasonable design and effectively improves upon the above mentioned disadvantages.

### SUMMARY OF THE INVENTION

The object of the present disclosure is to provide a multi-layer flexible circuit board and a process for producing the same, in order to reduce the product thickness so as to achieve product miniaturization, increase yield rate, and reduce crosstalk between electric circuits.

In order to achieve the aforementioned objects, the present disclosure provides a process for producing the multi-layer flexible circuit board, including at least the following steps: providing a flexible circuit board whose surface has a first electric circuit protruding therefrom and an empty portion which is empty with respect to the first electric circuit; coating an electric insulation layer on the surface of the flexible circuit board, such that the electric insulation layer fills up the empty portion to define a neighboring interval layer and covers the top portion of the first electric circuit to define a vertical interval layer on top of the first electric circuit; and making the electric insulation layer coat at least two sides of the first electric circuit.

In order to achieve the aforementioned objects, the present disclosure provides a multi-layer flexible circuit board including at least one electric circuit disposed on a vertical interval layer. The electric circuit is enclosed on at least two sides by a neighboring interval layer and a vertical interval layer formed by an electric insulation layer.

In summary, the present disclosure coats electric insulation layer on the surface of the flexible circuit board to form the aforementioned neighboring interval layer and vertical interval layer, thereby enclosing at least two sides of the first electric circuit to improve upon the oft-encountered problem of yield rate encountered in conventional pressing techniques and to reduce the thickness of the product. Also, the conventional production method involves large amount of etching, which increases the difficulty the production of multi-layer flexible circuit boards and wastes most of the material due to etching in a non-environmentally friendly manner. The present disclosure however does not require large amount of etching and is therefore, relative to conventional techniques, able to reduce thickness, reduce cost, attain independence of material sourcing, and reduce waste of material to be environmentally friendly.

Moreover, the electric insulation layer can provide electric shielding, thereby reducing crosstalk between electric circuits on the multi-layer flexible circuit board. In order to further the understanding regarding the present invention, the following embodiments are provided along with illustrations to facilitate the disclosure of the present invention.

### BRIEF DESCRIPTION OF THE DRAWINGS

FIG. 1A shows a flowchart of steps according to a first embodiment of the present disclosure;

FIG. 1B shows a schematic diagram of a chemical mechanism employed during conductivity treatment of a substrate according to a first embodiment of the present disclosure;

FIG. 1C shows a flowchart of steps of conductivity treatment according to a first embodiment of the present disclosure;

FIG. 2A to FIG. 2H are cross-sectional views corresponding to the steps of the first embodiment of the present disclosure;

FIG. 3 shows a flow chart of steps of the second embodiment of the present disclosure; and

FIG. 4A to FIG. 4K are cross-sectional views corresponding to the steps of the second embodiment of the present disclosure.

### DETAILED DESCRIPTION OF THE PREFERRED EMBODIMENTS

The aforementioned illustrations and following detailed descriptions are exemplary for the purpose of further explaining the scope of the present invention. Other objectives and advantages related to the present invention will be illustrated in the subsequent descriptions and appended drawings.

### First Embodiment

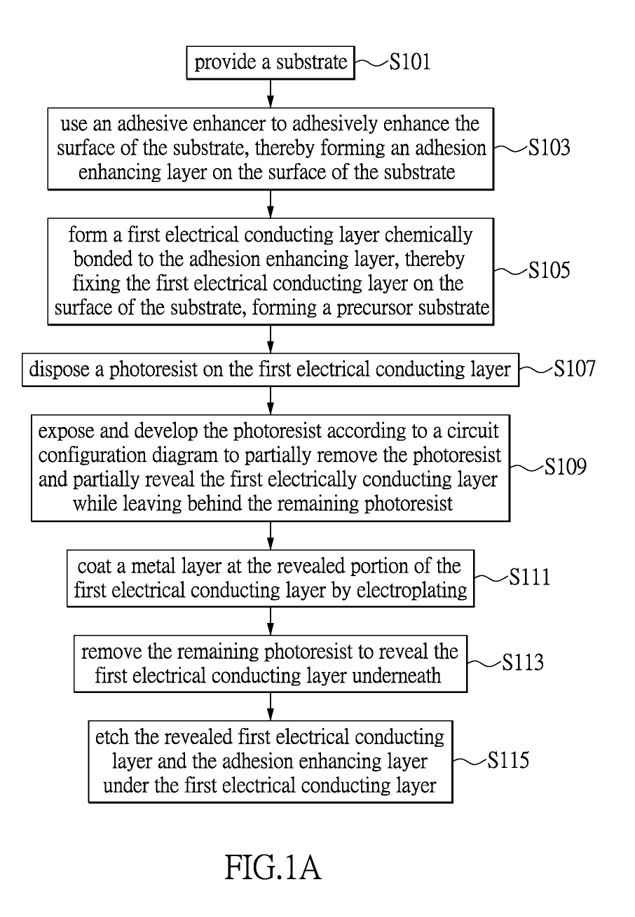

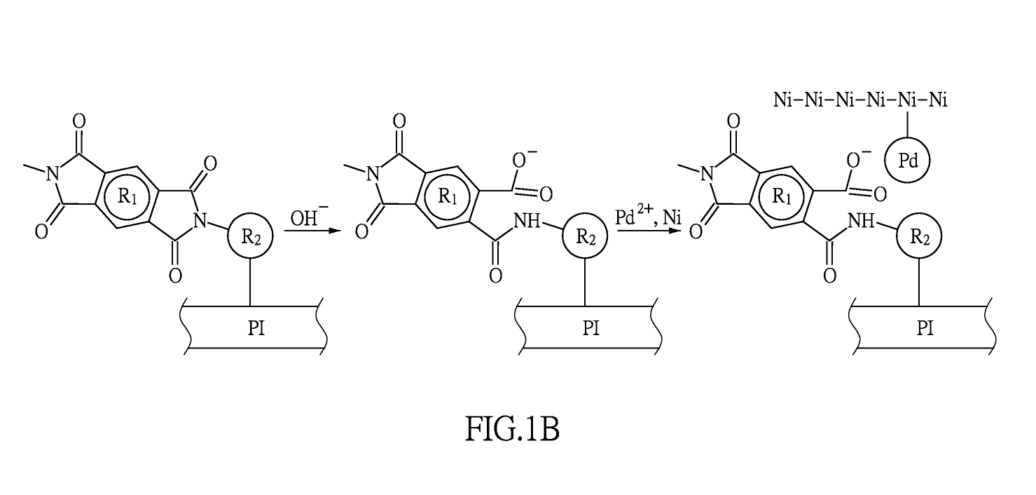

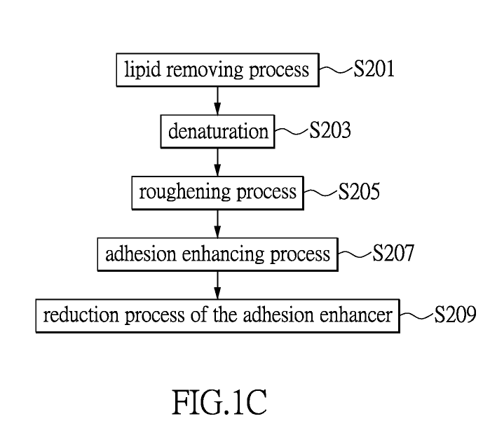

Referring to FIG. 1A which is a flowchart according to a first embodiment of the present disclosure, the present disclosure provides a process for producing a flexible circuit board, including the following steps.

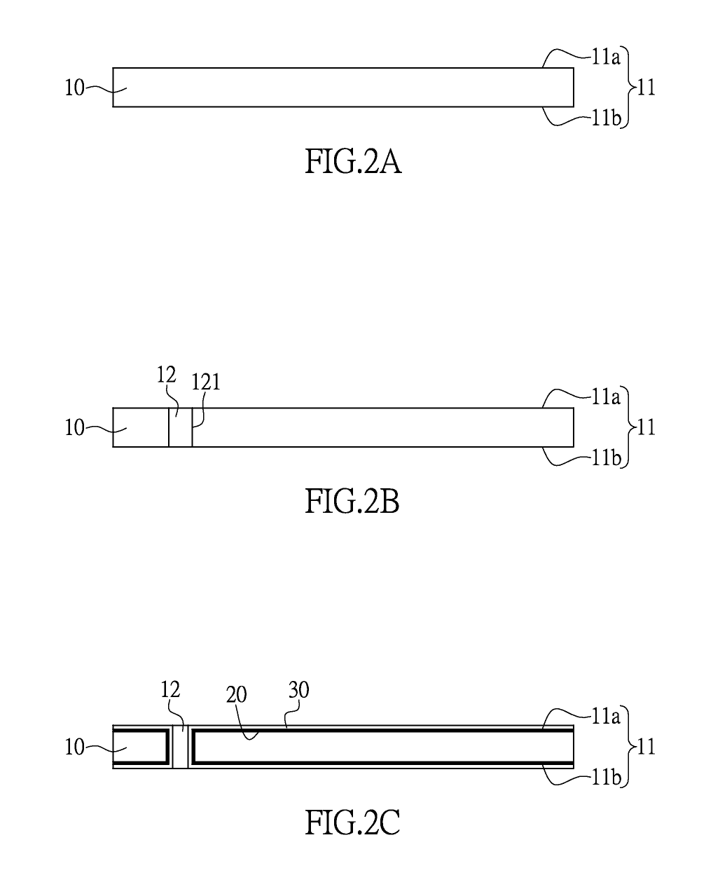

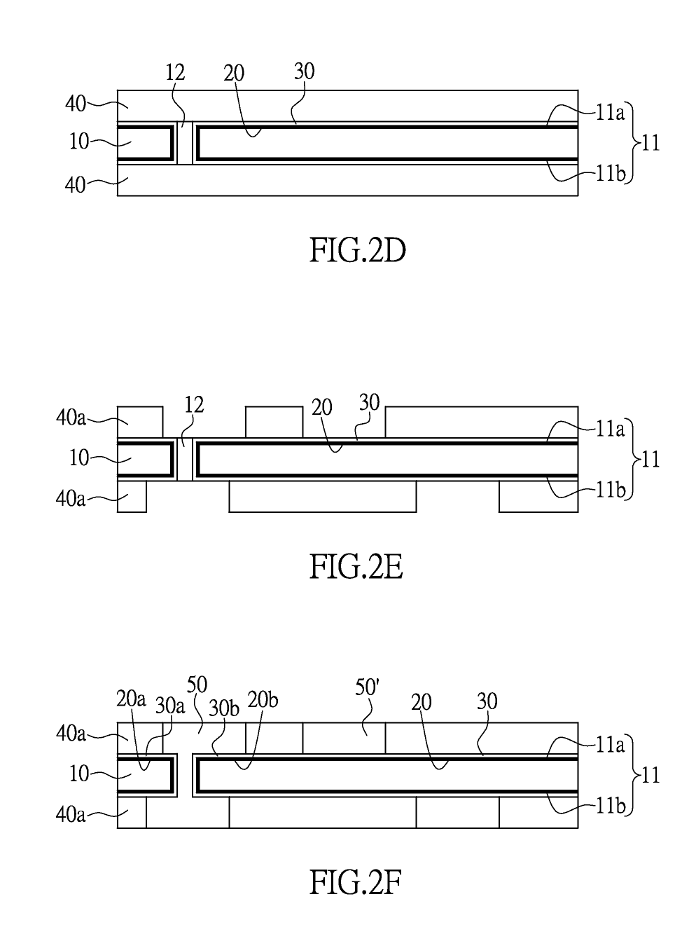

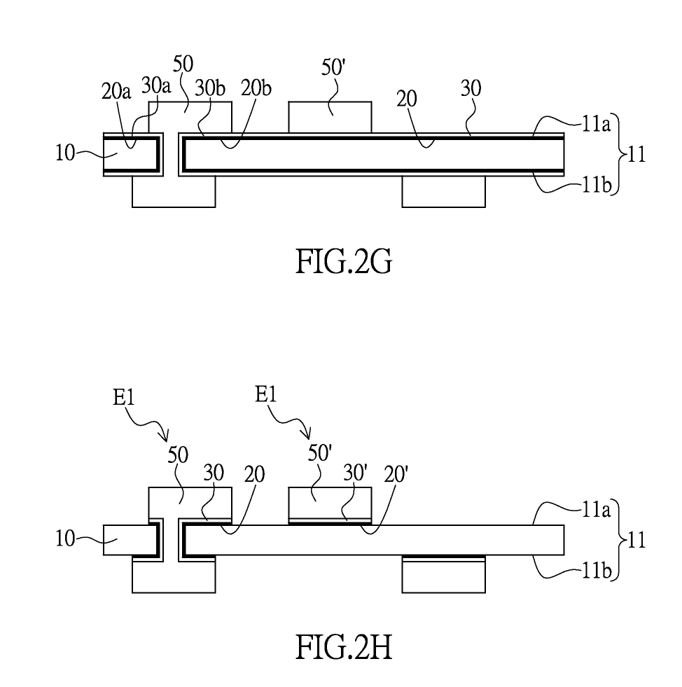

As shown in the cross-sectional diagram of FIG. 2A, provide a substrate 10 having a surface 11. The surface 11 of the substrate 10 includes an upper surface 11a and a lower surface 11b. The substrate is a raw material and can be polyimide (PI), polyethylene terephthalate polyester (PET), polyethylene naphthalate (PEN), polytetrafluorethylene (PETE), thermotropic liquid crystal polymer (LCP, epoxy, aramid or other macromolecular polymers. Referring to FIG. 2B, a via hole 12 can be bored by laser beam processing according to need on the substrate 10 interconnecting the upper surface 11a and the lower surface 11b. The via hole 12 has a tunnel wall 121 (step S101). Additionally the substrate 10 processed by laser beam can be cleaned by plasma to remove residue left from laser processing.

Referring to FIG. 2B and FIG. 2C, use an adhesive enhancer to adhesively enhance the surface 11 of the substrate 10, thereby forming an adhesion enhancing layer 20 on the surface 11 of the substrate 10. More specifically, the adhesion enhancing layer 20 is positioned on the upper surface 11a, the lower surface 11b and the tunnel wall 121 of the substrate 10 (step S103). In other words, the adhesion enhancing layer 20 can partially merge or fuse with the upper surface 11a, the lower surface 11b and the tunnel wall 121. Preferably, the adhesion enhancer is a palladium adhesion enhancer. Next, form a first electrical conducting layer 30 which chemically bonds with the adhesion enhancing layer 20. Assisted by the adhesion enhancing layer 20, the first electrical conducting layer 30 is fixed onto the upper surface 11a, the lower surface 11b and the tunnel wall 121 of the substrate, thereby completing the production (step S105) of a precursor substrate (label omitted).

Preferably, the first electric conducting layer 30 has a thickness of 50 to 200 nanometers and is a metal selected from the group consisting of copper, nickel, chromium, cobalt, nickel alloys and cobalt alloys. Since the first electrical conducting layer 30 is fixed onto the substrate 10 by an electroless plating method, it is also an electroless plating layer.

Referring to FIG. 2D, FIG. 2E, and FIG. 2F, dispose a layer of photoresist 40 on the first electrical conducting layer 30 on the upper surface 11a and the lower surface 11b of the substrate 10 (step S107). Preferably the type of photoresist is not limited, and can be a positive photoresist or a negative photoresist. The photoresist can be disposed by laminating or coating. Expose and develop the photoresist 40 according to a circuit configuration diagram to partially remove the photoresist 40 and partially reveal the first electrically conducting layer 30 while leaving behind the remaining photoresist 40a (step S109). Coat a metal layer at the revealed portion of the first electrical conducting layer 30 by electroplating (step S111). The metal layer is a second electrical conducting layer 50 or a second electrical conducting layer 50′. Hereby only the second electrical conducting layer 50 is further explained. The first electrical conducting layer and the adhesion enhancing layer under the second electrical conducting layer 50 are respectively labeled 30b and 20b. Under the remaining photoresist 40a are the first electrical conducting layer 30a and the adhesion enhancing layer 20a. Preferably the second electrical conducting layer 50 is copper, but is not limited hereto.

As shown in FIG. 2G and FIG. 2H, remove the remaining photoresist 40a to reveal the first electrical conducting layer 30a under the remaining photoresist 40a (step S113). Etch the revealed first electrical conducting layer 30a and the adhesion enhancing layer 20a underneath (step S115). The adhesion enhancing layer 20b and the first electrical conducting layer 30b under the second electric conducting layer 50 of FIG. 2G are renamed as adhesion enhancing layer 20 and first electrical conducting layer 30 in FIG. 2H. Given that the adhesion enhancing layer 20 and the first electrical conducting layer 30 formed on the substrate 10 are thinner compared to those in conventional techniques, the etching process of the present disclosure wastes less material which is more environmentally friendly.

In the present embodiment, referring to FIG. 2C, the substrate 10, the adhesion enhancing layer 20 and the first electrical conducting layer 30 are respectively made of polyimide, palladium and nickel, but are not limited hereto. Referring to FIG. 1B and FIG. 1C, the aforementioned step “use an adhesion enhancer to adhesively enhance the surface 11 of the substrate 10, forming an adhesion enhancing layer 20” further includes a conductivity treatment. The object is to enhance the adhesion between the surface 11 of the substrate 10 and the palladium adhesion enhancer. The first electrical conducting layer 30 is formed by disposing the nickel on the palladium adhesion enhancer, which serves an important role as a foundation for the nickel to adhere to the substrate 10. In other words, the nickel of the first electrical conducting layer 30 and the palladium of the adhesion enhancing layer can form a palladium-nickel alloy.

As shown in FIG. 1B, FIG. 1C and FIG. 2C, in order to enhance the adhesion between the surface of the substrate 10 and the palladium adhesion enhancer, the conductivity treatment includes the following steps on the substrate 10 surface: lipid removing process (step S201), denaturation (step S203), roughening process (step S205), adhesion enhancing process (step S207), and reduction process of the adhesion enhancer (step S209). In particular, the roughening process (step S205) includes chemical roughening or physical roughening. The chemical roughening includes using chemical agent on the surface of the substrate 10 to roughen by corrosion or ring-opening reactions. The physical roughening includes roughening the surface of the substrate 10 by mechanical means. Both methods improve adhesion of the surface of the substrate 10 to the palladium adhesion enhancer. The method of ring-opening reaction opens the molecular rings of the material of the substrate 10 to create unevenness in the molecular structure, to enhance adhesion between the palladium adhesion enhancer and the substrate 10. In other words, if ring opening occurs on the structure of polyimide for example, microscopically the substrate 10 is roughened, thereby creating an adhesion effect between the surface of the substrate 10 and the ions of the palladium adhesion enhancer, such that the ions of the palladium adhesion enhancer is easily fixed onto the substrate 10, forming the adhesion enhancing layer 20.

Furthermore as shown in FIG. 1B, roughening by chemical ring opening involves using a basic agent to cleave one of the carbon-nitrogen bond of imides (O═C—N—C═O) such that ring opening occurs in the polyimide on the substrate 10, and then using the palladium adhesion enhancer as a medium to increase adhesion between the polyimide and nickel, completing the process of electroless plating.

Referring to FIG. 1C in conjunction with FIG. 2A, FIG. 2B and FIG. 2C, when using ring opening as the roughening method, the following applies in the conductivity process:

The lipid removing process uses amino alcohol (H₂NCH₂CH₂CH₂OH, agent number ES-100) agent having pH between 10 and 11 and temperature between 45 and 55 degree Celsius to clean the surface of the substrate 10 for 1 to 3 minutes, in order to remove lipid.

The surface denaturation process uses a weak base having pH between 7.5 and 8.5 and temperature between 35 and 45 degree Celsius, such as sodium carbonate (agent number ES-FE) to clean the surface of the substrate 10 for 1 to 3 minutes, in order to restore the usual pH value on the surface of the substrate 10 and remove residual ES-100. However depending on the conditions after the previous steps, the present step can be skipped accordingly to achieve better effect.

The surface roughening process is chemical and uses inorganic base having pH between 11 and 12 and temperature between 45 and 55 degree Celsius, such as potassium hydroxide (KOH, agent number ES-200) but is not limited hereto, in order to perform basic denaturation on the substrate 10 for 1 to 3 minutes, such that one of the carbon-nitrogen bonds in the polyimide O═C—N—C═O is cleaved so ring opening occurs to the polyimide.

The adhesion enhancing process includes: using an adhesion enhancer to fix onto the surface of the substrate 10 to form an adhesion enhancing layer 20. More specifically, the present step involves palladium ions forming chemical bonds with the carbonyl group (O═C—O—) of ring-opened polyimide (using agent ES-300, including complex compound having palladium sulfate H₂SO₄.Pd₄, of a pH between 5.5 and 6.5 and between 45 and 55 degree Celsius, for 1 to 4 minutes).

The reduction process of the adhesion enhancer includes adhering a metal onto the adhesion enhancing layer 20, thereby merging the first electrical conducting layer 30 with the surface of the substrate 10. More specifically, the present process uses agent ES-400 whose main ingredient is boron (pH is between 6 and 8, the temperature is between 30 and 40 degree Celsius, the process time is between 1 to 3 minutes), to reduce palladium ions such that the palladium can adhere to metal (nickel). Next use agent ES-500 whose main ingredients are NiSO₄.6H₂O and NaH₂PO₂ (pH is between 8 and 9, temperature is between 35 and 45, processing time is between 3 and 5 minutes). The nickel easily adheres to the surface of the substrate with the palladium adhesion enhancer acting as an intermediary bonding medium. The nickel layer (first electrical conducting layer) has a thickness of 50 to 200 nanometers. After processing of the ES-500, the precipitated electroless plating of nickel has low amount of phosphorus (2-3%), therefore the first electrical conducting layer 30 is more ductile. The precipitation speed is 100 nm/5 minutes, which is faster than the conventional method, thereby saving production time and cost.

As an aside, in the figures of the present disclosure, the adhesion enhancing layer 20, the first electrical conducting layer 30, the top surface 11a, the lower surface 11b, and the tunnel wall 121 have clear boundaries delineated in the diagrams merely for schematic purposes. In practice, the adhesion between the first electrical conducting layer 30 or the adhesion enhancing layer 20 to the top surface 11a, the lower surface 11b or the inner wall 121 can include an integrated merging layer (omitted in the figures). This implies that the precursor substrate produced by the production method of the present disclosure has strong adhesion between each of its different layers.

Therefore, referring to FIG. 2H, according to the aforementioned production method, the present disclosure provides a flexible circuit board, including: at least one multilayer unit (label omitted) disposed on a substrate 10, including an adhesion enhancing layer 20, a first electrical conducting layer 30 and a second electrical conducting layer 50. The adhesion enhancing layer 20 is positioned on the surface 11 of the substrate 10. The surface 11 includes the top surface 11a or the lower surface 11b. The first electrical conducting layer 30 adheres to the adhesion enhancing layer 20. The second electrical conducting layer 50 is positioned on top of the first electrical conducting layer 30.

Preferably, the production method of the material of the substrate 10 is similar to the above. The material of the substrate 10 is at least one material selected from the group consisting of polyimide, polyester, polyethylene terephthalate, polytetrafluoroethylene, liquid crystal polymer, epoxy resin and aramid. The first electrical conducting layer 30 has a thickness of 50 to 200 nanometers and is an electroless plating layer made of a material selected from the group consisting of copper, nickel, chromium, cobalt, nickel alloys and cobalt alloys. The adhesion enhancing layer includes a palladium adhesion enhancer.

Additionally, referring to FIG. 2B, FIG. 2C and FIG. 2H, the substrate 10 has a via hole 12 running in the vertical direction connecting the top surface 11a and the lower surface 11b. The multilayer unit is respectively disposed on the top surface 11a and the lower surface 11b and is positioned on the via hole 12. The adhesion enhancing layer 20 and the first electrical conducting layer 30 of the multilayer unit further extends along the tunnel wall 121 of the via hole 12. The second electrical conducting layer 50 also extends along the via hole 12, thereby electrically interconnecting the multilayer unit on the upper surface 11a and the multilayer unit on the lower surface 11b. The adhesion enhancing layer 20′, the first electrical conducting layer 30′ and the second electrical conducting layer 50′ in FIG. 2H do not extend into the via hole 12.

More specifically, when the second electrical conducting layer 50 extends into the via hole 12, the multilayer units of the upper surface 11a and the lower surface 11b are electrically connected by the first electrically conducting layer 30 or the second electrically conducting layer 50 itself which fills up the via hole 12. The adhesion enhancing layer 20 is preferably a palladium adhesion enhancer. The multilayer units can overall form a first electrical circuit E1. The multilayer units can be electrically connected or not electrically connected.

### Second Embodiment

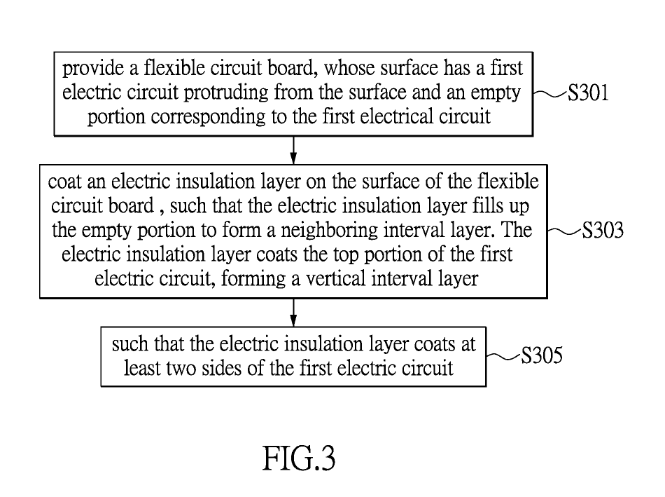

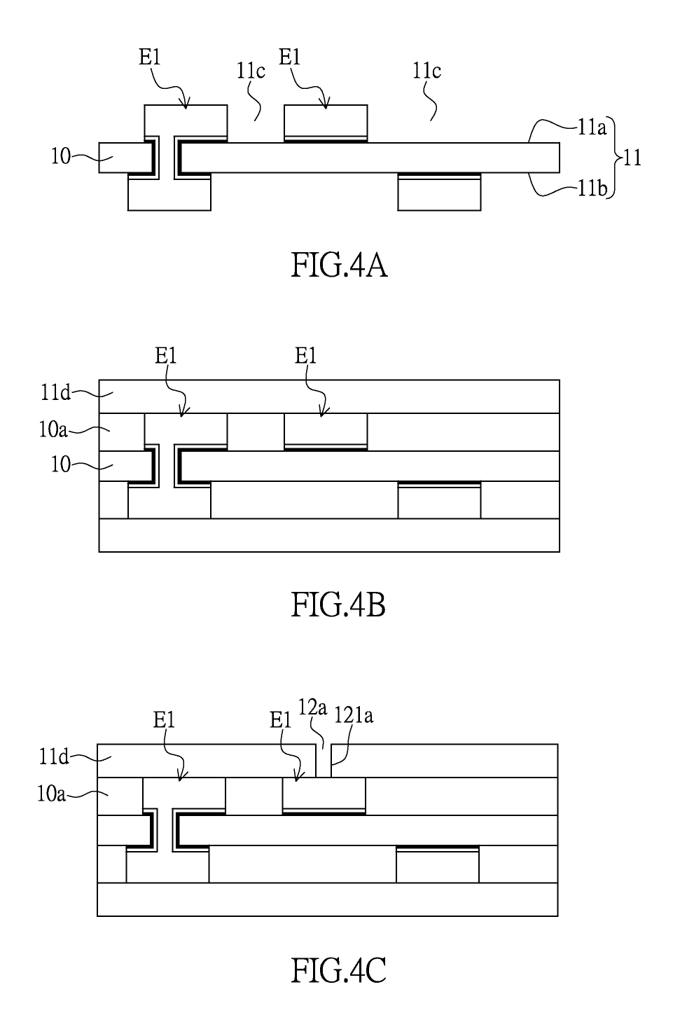

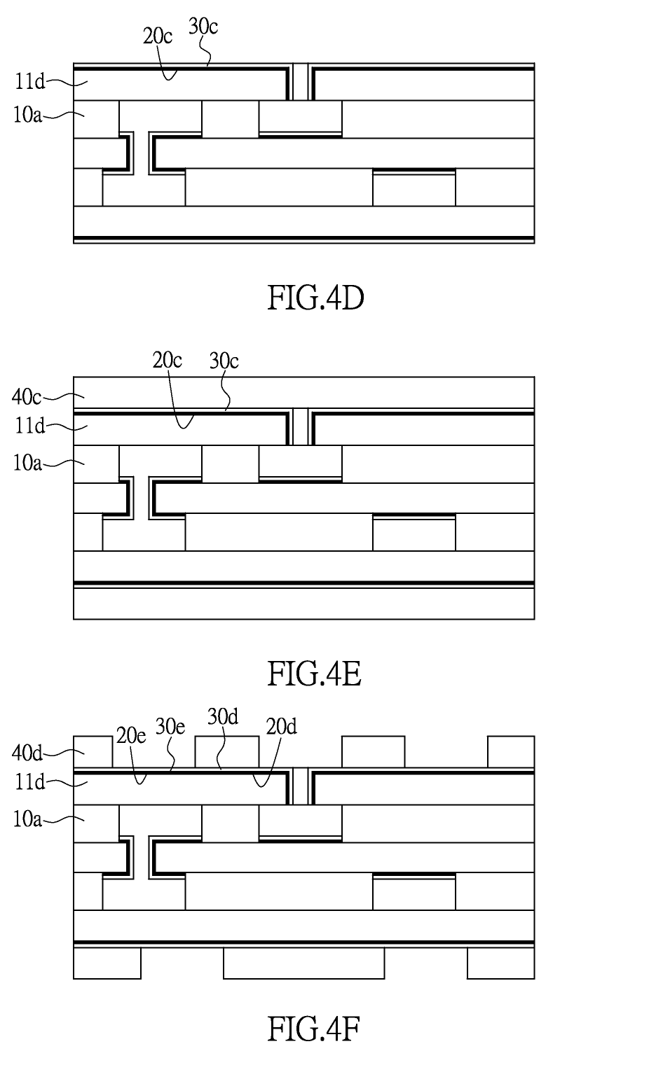

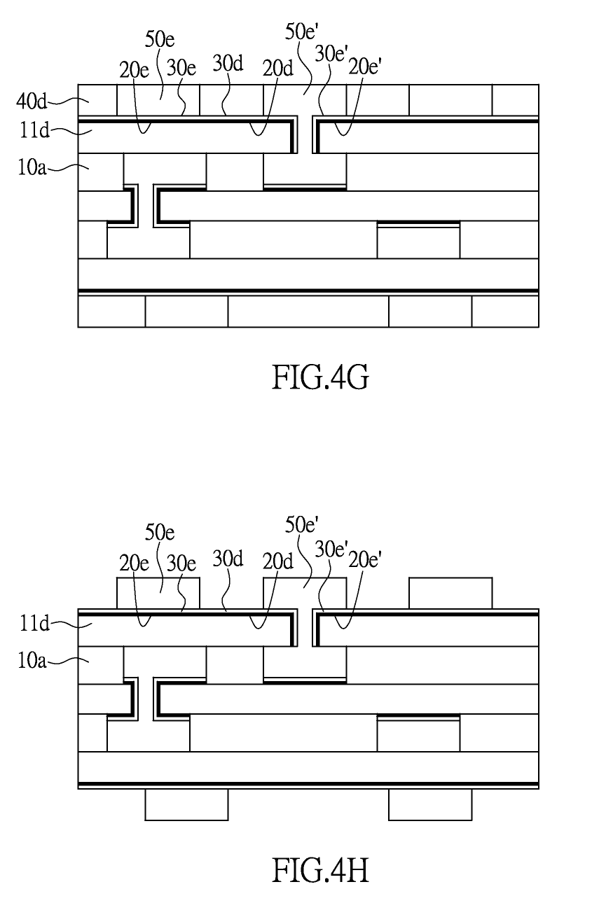

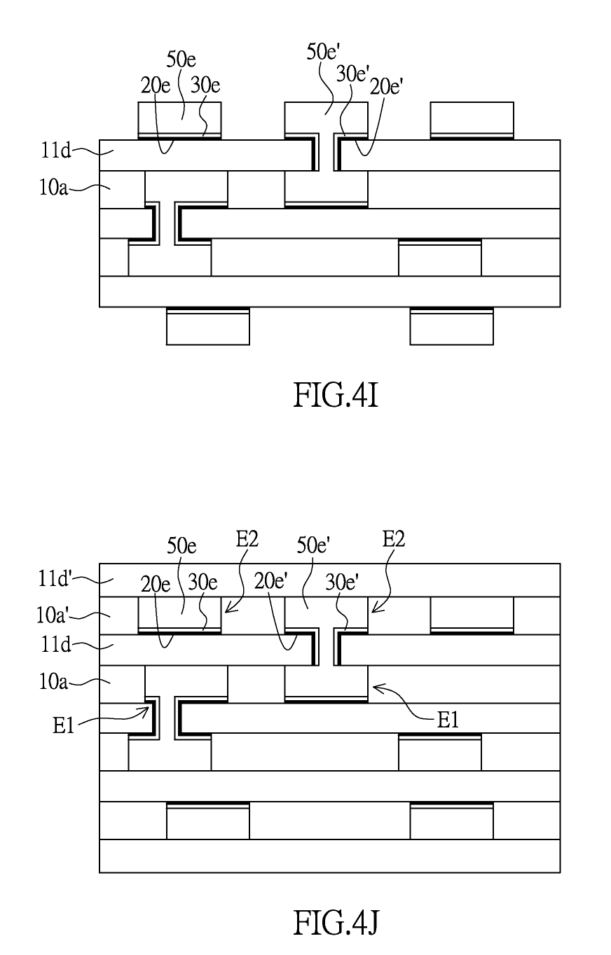

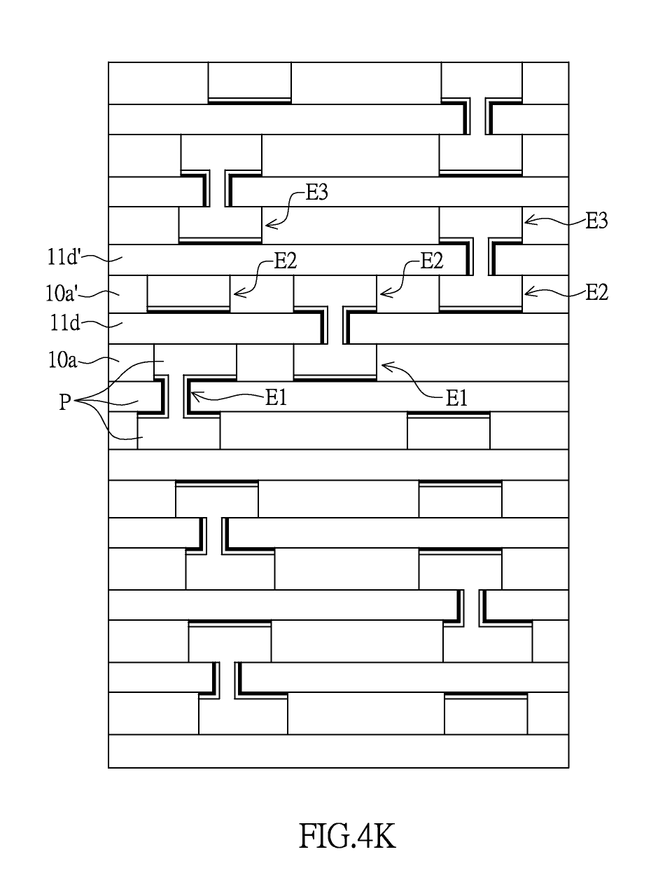

In another embodiment, as shown in the flowchart of FIG. 3 in conjunction with cross-sectional views of FIG. 4A, FIG. 4B, and FIG. 4C, the present disclosure provides a method of manufacturing a multi-layer flexible circuit board, including the following steps. Provide a flexible circuit board P whose surface 11 includes an upper surface 11a and a lower surface 11b. The surface 11 has a first electric circuit E1 protruding from the surface 11 and an empty portion 11c having no first electrical circuit E1 (step S301). Coat an electric insulation layer on the surface 11 of the flexible circuit board P, such that the electric insulation layer fills up the empty portion 11c to form a neighboring interval layer 10a. The electric insulation layer coats the top portion of the first electric circuit E1, forming a vertical interval layer 11d (step S303) such that the electric insulation layer coats at least two sides of the first electric circuit E1 (step S305).

Preferably, the electric insulation layer is made of a material selected from the group consisting of polyimide film, polyamic acid (PAA), polyethylene terephthalate, polyethylene, liquid crystal polymer, epoxy resin, polyphenylene sulfide and photosensitive cover film.

If the electric insulation layer is preferably embodied by polyamic acid, after coating the polyamic acid to form a neighboring interval layer 10a and a vertical interval layer 11d, the neighboring interval layer 10a and the vertical interval layer 11d can be cured such that the polyamic acid becomes (develops rings) polyimide. The curing occurs at 300 degree Celsius, in an environment full of nitrogen with infrared light beaming on the polyamic acid. After the polyamic acid becomes polyimide, a via hole 12a having a tunnel wall 121a can be bore through the vertical interval layer 11d such that the via hole 12a is connected to the first electric circuit E1.

Referring to cross-sectional views of FIG. 4D, FIG. 4E and FIG. 4F, the present production method includes the following steps.

Use an adhesion enhancer to adhesively enhance the surface of the vertical interval layer 11d, thereby forming an adhesion enhancing layer 20c on the surface of the vertical interval layer 11d. Form a first electrical conducting layer 30c for chemically bonding with the adhesion enhancing layer 20c, thereby assisting the first electrical conducting layer 30c to be fixed onto the surface of the vertical interval layer 11d.

Dispose a photoresist 40c on the surface of the first electrical conducting layer 30c.

Expose and develop the photoresist 40c according to a circuit configuration diagram to partially remove the photoresist 40c and partially reveal the first electrically conducting layer 30e while leaving behind a remaining photoresist 40d.

Referring to FIG. 4G, FIG. 4H, FIG. 4I and FIG. 4J, coat a metal layer on the revealed portion of the first electrical conducing layer (namely the first electrical conducting layer 30e) to form a second electric circuit E2 by electroplating. The second electric circuit can extend into the via hole (label omitted) to electrically connect to the first electric circuit (positioned in the neighboring interval layer 10a, label omitted). Remove the remaining photoresist 40d to reveal the first electrical conducting layer 30d under the remaining photoresist 40d. Underneath the first electrical conducting layer 30d is the adhesion enhancing layer 20d. Etch the revealed first electrical conducting layer 30d and the adhesion enhancing layer 20d underneath. In this manner a multilayer unit (label omitted) having the adhesion enhancing layer 20e, the first electrical conducting layer 30e and the second electrical conducting layer 50e can be formed on the vertical interval layer 11d. Additionally, the same applies to the other multilayer unit formed having the adhesion enhancing layer 20e′, the first electrical conducting layer 30e′ and the second electrical conducting layer 50e′. Given that the two multilayer units are positioned on the same vertical interval layer 11d, they are considered as part of the second electric circuit E2, even though the two multilayer units can be mutually independent circuits. Even though the second electrical conducting layer 50e in the multilayer unit is an independent circuit, the second electrical conducting layer 50e′, the first electrical conducting layer 30e′ and the adhesion enhancing unit 20e′ in the other multilayer unit can be similar to the previous embodiments, passing through the vertical interval layer 11d via the via hole (label omitted) to further electrically connect to the second electrical conducting layer 50b′ of the first electric circuit E1, improving versatility of the electric circuit configuration.

Additionally, referring to FIG. 4J, the second electric circuit E2 can be enclosed by a neighboring interval layer 10a′ and a vertical interval layer 11d′. The neighboring interval layer 10a′ and the vertical interval layer 11d′ are likewise formed by curing polyamic acid into polyimide. Therefore comparing FIG. 4A and FIG. 4J, it can be seen that through curing of the polyamic acid, electric circuits can be added on the upper surface 11a or the lower surface 11b of the flexible circuit board P.

Of course, when forming the multilayer unit which make up electric circuit on the flexible circuit board P as shown in FIG. 4A, a conductivity treatment can be included just like the first embodiment, whose detailed process is described in the first embodiment, especially the processes of surface roughening and adhesion enhancing on the surface of the vertical interval layer 11d, such that the multilayer unit of the first electric circuit E1, the second electric circuit E2 or any other electric circuit can have an adhesion enhancing layer (label omitted), hereby not further detailed.

The second embodiment can be interpreted as an extended application of the first embodiment, and adds the multilayer structure of stacked polyamic acid converted to polyimide. Referring to FIG. 4J and FIG. 4K, the present disclosure provides a multi-layer flexible circuit board, whose multi-layer electric-circuit configuration includes at least one electric circuit (label omitted), which can be disposed on the vertical interval layer 11d of FIG. 4J. The electric circuit, for example as shown in FIG. 4J, can include: a vertical interval layer 11d, an adhesion enhancing layer 20e (or adhesion enhancing layer 20e′), a first electrical conducting layer 30e (or a first electrical conducting layer 30e′) and a second electrical conducting layer 50e (or a second electrical conducting layer 50e′). The adhesion enhancing layer 20e is formed on the surface of the vertical interval layer 11d. The first electrical conducting layer 30e is formed on the adhesion enhancing layer 20e. The second electrical conducting layer 50e is formed on the first electrical conducting layer 30e. The first electrical conducting layer 30e and the second electrical conducting layer 50e both make up the second electric circuit E2 on the vertical interval layer 11d.

In FIG. 4J, the second electrical conducting layer 50e′, the first electrical conducting layer 30e′ and the adhesion enhancing layer 20e′ all belong to the second electric circuit E2. However they do not have to be mutually electrically connected. In order to keep the circuit design versatile, for example the second electrical conducting layer 50e′ can cross the vertical interval layer 11d to electrically connect to part of the first electric circuit E1. Any of the aforementioned electric circuit, for example the first electric circuit E1 and the second electric circuit E2 in the figures, is enclosed by neighboring interval layer (10a, 10a′) and vertical interval layer (11d, 11d′) formed by polyamic acid converted to polyimide. At least the left and right sides of the electric circuit of the flexible circuit board are enclosed and directly in contact with polyimide. Similarly, a third electric circuit E3 and more can be constructed.

It can be seen from FIG. 4K, that the exemplified multi-layer flexible circuit board P with ten layers already includes two layers of circuits having the first electric circuit E1. According to the above method, additional layers can be progressively stacked above and below. The present embodiment respectively adds 4 layers on each side of the flexible circuit board P to form 10 layers (2+4+4) of circuits. In view of the concept of vertical interval layers introduced in the present embodiment, as shown in FIG. 2H of the first embodiment, the substrate 10 can be broadly viewed as a vertical interval layer. Likewise the substrate of FIG. 4A and FIG. 4B can also be viewed as a vertical interval layer.

However, even though the above example includes an adhesion enhancing layer (20e, 20e′), they are merely preferred embodiments and not strictly required. Likewise the electric insulation layer does not have to be formed by polyamic acid converting into polyimide. However if the electric insulation layer uses polyamic acid, but the electric circuit (or the multilayer unit) is conventional and does not have an adhesion enhancing layer, then the present embodiment can still form the polyamic acid on a conventional flexible circuit board to coat a conventional electric circuit, and cure the polyamic acid into polyimide to simplify the production of the multi-layer flexible circuit board, facilitating production. Additionally, through the enclosing provided by the polyimide and other electric insulation material, cross-talk is reduced between the many electric circuits on the flexible circuit board, resulting in better transmission quality.

### Third Embodiment

Returning to FIG. 2A, FIG. 2B and FIG. 2C, the present disclosure further provides a precursor substrate (label omitted) as a partially finished product of a circuit board, to be used in subsequent circuit board processing. The precursor substrate includes at least: a substrate 10 and a first electrical conducting layer 30. The substrate 10 has a surface 11 which is adhesively enhanced. The adhesively enhanced surface 11 includes an adhesion enhancing layer 20. The first electrical conducting layer 30 adheres to the adhesion enhancing layer 20 such that the first electrical conducting layer 30 encloses the surface 11 of the substrate 10.

Preferably, the material of the substrate is polyimide; the adhesion enhancing layer 20 includes a palladium adhesion enhancer; the thickness of the first electrical conducting layer 30 is between 50 and 200 nanometers; and the first electrical conducting layer 30 is an electroless plating layer made of a material selected from the group consisting of copper, nickel, chromium, cobalt, nickel alloys and cobalt alloys.

Preferably, the surface includes an upper surface 11a and a lower surface 11b, the substrate has a via hole 12 connecting the upper surface 11a and the lower surface 11b, the via hole has a tunnel wall 121. Broadly speaking, the surface 11 of the substrate 10 includes the upper surface 11a, the lower surface 11b and the tunnel wall 121, all of which can be adhesively enhanced and include the adhesive enhancing layer 20. Thusly, the first electrical conducting layer 30 can be distributed by the adhesion enhancing layer 20 and coat the surface 11 of the substrate 10 including the upper surface 11a, the lower surface 11b and the tunnel wall 121.

The descriptions illustrated supra set forth simply the preferred embodiments of the present invention; however, the characteristics of the present invention are by no means restricted thereto. All changes, alternations, or modifications conveniently considered by those skilled in the art are deemed to be encompassed within the scope of the present invention delineated by the following claims.

What is claimed is:

1. A method of manufacturing a flexible circuit board, comprising at least:
providing a flexible circuit board whose surface has a first electric circuit protruding therefrom and an empty portion which is empty with respect to the first electric circuit;
coating an electric insulation layer on the surface of the flexible circuit board, such that the electric insulation layer fills up the empty portion to define a neighboring interval layer and covers the top portion of the first electric circuit to define a vertical interval layer on top of the first electric circuit; and
making the electric insulation layer coat at least two sides of the first electric circuit.

2. The method of manufacturing a flexible circuit board according to claim 1, wherein the electric insulation layer is made of a material selected from the group consisting of polyimide film, polyamic acid, polyethylene terephthalate, polyethylene, liquid crystal polymer, epoxy resin, polyphenylene sulfide and photosensitive cover film.

3. The method of manufacturing a flexible circuit board according to claim 1, wherein the electric insulation layer uses a polyamic acid, and includes the neighboring interval layer and the vertical interval layer cured from polyamic acid into polyimide, such that the polyimide encloses two sides of the first electric circuit.

4. The method of manufacturing a flexible circuit board according to claim 3, further comprising the following steps:
adhesively enhancing the surface of the substrate by using an adhesion enhancer, forming an adhesion enhancing layer on the surface of the substrate;
forming a first electrical conducting layer chemically bonded to the adhesion enhancing layer, thereby forming fixing the first electrical conducting layer onto the surface of the vertical interval layer;
disposing a photoresist on the first electrical conducting layer;
exposing and developing the photoresist according to a circuit configuration diagram to partially remove the photoresist and partially reveal the first electrically conducting layer while leaving behind a remaining photoresist;
coating a metal layer on the revealed portion of the first electrical conducting layer to form a second electric circuit;
removing the remaining photoresist to reveal the first electrical conducting layer under the remaining photoresist;
etching to remove the revealed first electrical conducting layer and the adhesion enhancing layer under the revealed first electrical conducting layer; and
coating polyamic acid on the second electric circuit such that after the polyamic acid becomes polyimide after curing, at least two sides of the second electric circuit are enclosed.

5. The method of manufacturing a flexible circuit board according to claim 4, wherein after the polyamic acid becomes polyimide, a via hole is vertically bore in the vertical interval layer, such that the via hole connects to the first electric circuit, thereby electrically connecting the aft-formed second electric circuit with the first electric circuit.

6. The method of manufacturing a flexible circuit board according to claim 4, wherein in the step of using an adhesive enhancer to form an adhesion enhancing layer on the surface of the vertical interval layer, conductivity treatment is included, and the conductivity treatment includes at least steps of surface roughening and adhesive enhancement of the surface of the vertical interval layer.

7. The method of manufacturing a flexible circuit board according to claim 6, wherein the roughening process on the surface of the substrate is chemical roughening, and the chemical roughening includes using chemical agent on the surface of the substrate to roughen by corrosion or ring-opening reactions.

8. The method of manufacturing a flexible circuit board according to claim 6, wherein the roughening process on the surface of the substrate is physical roughening, and the physical roughening includes roughening the surface of the substrate by mechanical means.

9. The method of manufacturing a flexible circuit board according to claim 4, wherein the adhesion enhancer is a palladium adhesion enhancer.

10. The method of manufacturing a flexible circuit board according to claim 5, wherein the adhesion enhancer is a palladium adhesion enhancer.

11. The method of manufacturing a flexible circuit board according to claim 6, wherein the adhesion enhancer is a palladium adhesion enhancer.

12. The method of manufacturing a flexible circuit board according to claim 7, wherein the adhesion enhancer is a palladium adhesion enhancer.

13. The method of manufacturing a flexible circuit board according to claim 8, wherein the adhesion enhancer is a palladium adhesion enhancer.

14. A multi-layer flexible circuit board, comprising:
at least an electric circuit disposed on a vertical interval layer, wherein the electric circuit is enclosed by a neighboring interval layer and another vertical interval layer formed by an electric insulation layer, and at least two sides of the electric circuit is enclosed.

15. The multi-layer flexible circuit board according to claim 14, wherein the electric circuit comprises a multilayer unit, which includes:
an adhesion enhancing layer disposed on the surface of the substrate;
a first electrical conducting layer adhered onto the adhesion enhancing layer; and
a second electrical conducting layer disposed on the first electrical conducting layer.

16. The multi-layer flexible circuit board according to claim 15, wherein the first electrical conducting layer has a thickness of 50 to 200 nanomenters, and the first electrical conducting layer is an electroless plating layer made of a material selected from the group consisting of copper, nickel, chromium, cobalt, nickel alloys and cobalt alloys.

17. The multi-layer flexible circuit board according to claim 14, wherein the vertical interval layer has a via hole, and the electric circuit electrically connects through the via hole to another electric circuit at another side of the vertical interval layer.

18. The multi-layer flexible circuit board according to claim 15, wherein the adhesion enhancing layer includes a palladium adhesion enhancer.

19. The multi-layer flexible circuit board according to claim 16, wherein the adhesion enhancing layer includes a palladium adhesion enhancer.

20. The multi-layer flexible circuit board according to claim 17, wherein the adhesion enhancing layer includes a palladium adhesion enhancer.
